(19) United States
(12) Patent Application Publication
(10) Pub. No.: US 2017/0219751 A1
(43) Pub. Date: Aug. 3, 2017

(54) POLARIZING FILM AND OPTICAL FILM AND DISPLAY DEVICE

(71) Applicants: SAMSUNG ELECTRONICS CO., LTD., Suwon-si (KR); Samsung SDI Co., Ltd., Yongin-si (KR)

(72) Inventors: Feifei FANG, Suwon-si (KR); Beom Seok KIM, Seoul (KR); Seong-Jun YOON, Yongin-si (KR); Dong Yun LEE, Suwon-si (KR); Myungsup JUNG, Seongnam-si (KR); Boreum JEONG, Daejeon (KR)

(21) Appl. No.: 15/229,654

(22) Filed: Aug. 5, 2016

(30) Foreign Application Priority Data
Jan. 29, 2016 (KR) 10-2016-0011952

(51) Int. Cl. G02B 5/30; C08F 110/06; C09B 67/36; H01L 51/52; C08K 5/00; C08J 3/20; G02F 1/1335; C08J 5/18; C09B 67/02

(52) U.S. Cl. CPC G02B 5/3033; C08J 5/18; C08F 110/06; C09B 67/0079; C09B 67/0097; C08K 5/0041; C08J 3/20; G02B 5/3083; G02F 1/133528; H01L 51/5293; C08J 2323/12

(57) ABSTRACT

A polarizing film includes a hydrophobic polymer and a dichroic dye, wherein the hydrophobic polymer includes a polypropylene polymer including about 0.5 mol % or less of an ethylene content (mol %), and has a distribution of a molecular weight of about 1 to about 5.

### CROSS-REFERENCE TO RELATED APPLICATION

This application claims priority to and the benefit of Korean Patent Application No. 10-2016-0011952 filed in the Korean Intellectual Property Office on Jan. 29, 2016, and all the benefits accruing therefrom under 35 U.S.C. §119, the content of which is incorporated herein by reference in its entirety.

### BACKGROUND

1. Field

A polarizing film, an optical film, and a display device are disclosed.

2. Description of the Related Art

A display device such as a liquid crystal display (LCD) and an organic light emitting diode (OLED) includes a polarizing plate attached to the outside of the display panel. The polarizing plate only transmits light of a specific wavelength range and absorbs or reflects other light, so it may control the direction of incident light on the display panel or light emitted from the display panel.

However, a polarizing plate including a polarizer and a protective layer not only involves a complicated process and high production costs, but also may result in a thick polarizing plate which leads to an increased thickness of a display device.

Accordingly, a polarizing film that does not include a protective layer has been researched. The polarization film without a separate protecting layer may be useful in developing a thin display device.

### SUMMARY

An embodiment provides a polarizing film capable of preventing degradation of optical properties.

Another embodiment provides an optical film including the polarization film.

Yet another embodiment provides a display device including the polarization film or the optical film.

According to an embodiment, a polarizing film includes a hydrophobic polymer and a dichroic dye, wherein the hydrophobic polymer includes a polypropylene polymer including about 0.5 mol % or less of an ethylene content (mol %), and has a distribution of a molecular weight of about 1 to about 5.

The polypropylene polymer may include about 0.01 parts per million (ppm) or greater of zirconium or hafnium.

The polypropylene polymer may include about 0.05 ppm to about 50 ppm of zirconium or hafnium.

The polypropylene polymer may include about 1.0 ppm or less of magnesium and about 0.5 ppm or less of titanium.

The polypropylene-based polymer may have a melt flow index of about 0.1 grams per 10 minutes (g/10 min) to about 15 g/10 min.

The hydrophobic polymer may further include a polyethylene-polypropylene copolymer including an ethylene content (mol %) in an amount of greater than about 0.5 mol %.

The polyethylene-polypropylene copolymer may have a distribution of a molecular weight of about 1 to about 5.

The dichroic dye may include at least one dichroic dye having a maximum absorption wavelength (λₘₐₓ) at about 380 nm to about 780 nm.

The dichroic dye may be included in an amount of about 0.01 to 2 parts by weight based on 100 parts by weight of the hydrophobic polymer.

The polarizing film may be a melt-blend of the hydrophobic polymer and the dichroic dye.

The polarizing film may be elongated in a uniaxial direction.

The polarizing film may have a light transmittance variation ratio (ΔT) of about 1.0% or less and a variation ratio of polarization efficiency (ΔPE) of about 1.0% or less, after standing at about 85° C. for about 100 hours.

According to another embodiment, a method of manufacturing a polarizing film includes polymerizing a monomer including propylene using a zirconocene catalyst or a hafnocene catalyst to prepare a polypropylene polymer including about 0.5 mol % or less of an ethylene content (mol %) and having a distribution of a molecular weight of about 1 to about 5, melt-blending a hydrophobic polymer including the polypropylene polymer and a dichroic dye at a temperature of greater than or equal to a melting point of the hydrophobic polymer, molding the melt-blend, and elongating a molded body.

In the preparing of the polypropylene polymer, the zirconocene catalyst or the hafnocene catalyst may be included in an amount of about 0.0001 millimole (mmol) to about 0.1 mmol based on 1 mol of the propylene-containing monomer.

The hydrophobic polymer may further include a polyethylene-polypropylene copolymer including an ethylene content (mol %) in an amount of greater than about 0.5 mol %.

The polyethylene-polypropylene copolymer may have a distribution of a molecular weight of about 1 to about 5.

According to another embodiment, an optical film includes the polarizing film and a retardation film disposed on the polarizing film.

The retardation film may include a λ/4 retardation film, a λ/2 retardation film, or a combination thereof.

According to another embodiment, a display device includes the polarizing film.

According to another, a display device includes the optical film.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a schematic view of a polarization film according to an embodiment;

FIG. 2 is a schematic cross-sectional view of an optical film according to an embodiment;

FIG. 3 is a schematic view showing a mechanism for preventing reflection of external light in an optical film according to an embodiment;

FIG. 4 is a cross-sectional view of a liquid crystal display (LCD) according to an embodiment; and

FIG. 5 is a cross-sectional view of an organic light emitting diode (OLED) display according to an embodiment.

### DETAILED DESCRIPTION

Exemplary embodiments will hereinafter be described in detail, and may be easily performed by those who have common knowledge in the related art. However, actually applied structures may be embodied in many different forms and is not construed as limited to the exemplary embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. “At least one” is not to be construed as limiting “a” or “an.” “Or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross sectional illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a polarization film according to an embodiment is described.

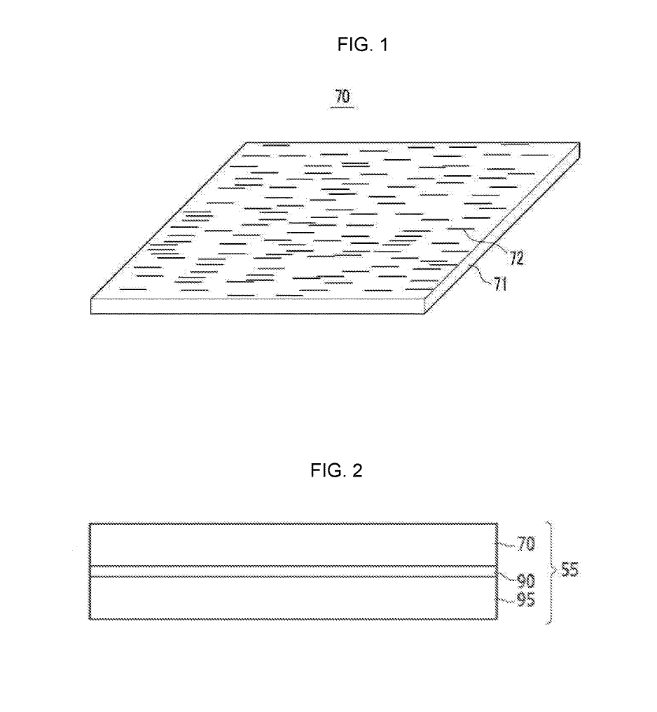

FIG. 1 is a schematic view of a polarization film according to an embodiment.

Referring to FIG. 1, a polarizing film 70 according to an embodiment includes a hydrophobic polymer 71 and a dichroic dye 72 dispersed in the hydrophobic polymer 71.

The dichroic dye 72 is dispersed in the hydrophobic polymer 71, and is substantially aligned in a single direction along the elongation direction of the hydrophobic polymer 71. The dichroic dye 72 may have, for example, a rod shape that is long in one direction. The dichroic dye 72 may transmit one polarizing perpendicular component out of two polarizing perpendicular components in a predetermined wavelength region.

The dichroic dye 72 may include at least one dichroic dye having a maximum absorption wavelength (λₘₐₓ) in a visible light region, for example, one or more dichroic dye having a maximum absorption wavelength (λₘₐₓ) at about 380 nm to about 780 nm. For example, dichroic dye 72 may include at least two dichroic dyes having a different maximum absorption wavelength (λₘₐₓ).

The decomposition temperature of the dichroic dye 72 may be about 245° C. or greater. Herein, the decomposition temperature indicates a temperature at which the weight of the dichroic dye 72 decreases by about 5% relative to its initial weight.

The dichroic dye 72 may be included in an amount of about 0.01 to about 5 parts by weight, based on 100 parts by weight of the hydrophobic polymer 71. Within this range, sufficient polarization characteristics may be obtained without deteriorating transmittance of a polarization film. Within the above range, the dichroic dye 72 may be included in an amount of about 0.01 to about 2 parts by weight, or about 0.05 to about 2 parts by weight based on 100 parts by weight, based on 100 parts by weight of the hydrophobic polymer 71.

The hydrophobic polymer 71 may include a polyolefin, for example a polypropylene-based polymer.

The polypropylene-based polymer may include a random copolymer including propylene as a main structural unit and a small amount of other randomly-disposed structural units, as well as a polypropylene homopolymer including only a propylene structural unit.

The polypropylene-based polymer may be, for example, a polypropylene homopolymer or a polypropylene random copolymer including a propylene structural unit as a main structural unit and a small amount of an ethylene content (mol %). The polypropylene-based polymer may be, for example a polypropylene homopolymer or a polypropylene random polymer including a propylene structural unit as a main structural unit and about 0.5 mol % or less of an ethylene content (mol %). The polypropylene-based polymer may include an ethylene content (mol %), for example, in an amount of about 0 to about 0.5 mol %, for example, in an amount of about 0 mol % to about 0.4 mol %, and for example, in an amount of about 0 mol % to about 0.2 mol % within the range.

The polypropylene-based polymer may have a distribution of a molecular weight of about 1 to about 5. As used herein, the term “distribution of a molecular weight” means a range of distribution of polymer molecular weights based on the average molecular weight of the polymer molecule chains When the distribution of a molecular weight is small, the polymer molecular weights are distributed within a narrow range based on the average molecular weight of the polymer molecule chains, but when the distribution of a molecular weight is large, the molecular weights are distributed within a wide range based on the average molecular weight of the polymer molecule chains. For example, when the distribution of a molecular weight is small, the range in the length of polymer molecule chains included in a polymer is more uniform, and thus the chains may be more regular. When the distribution of a molecular weight is large, the range in the length of the polymer molecule chains included in a polymer are not uniform, and thus the chains may be less regular. For example, the distribution of a molecular weight may be obtained as a ratio of a weight average molecular weight to a number average molecular weight. The polypropylene-based polymer may for example, have a distribution of a molecular weight ranging from about 1.5 to about 4.5, about 1.8 to about 4.3, and about 2.0 to about 4.0 within the range.

When the polypropylene-based polymer has a distribution of a molecular weight within the range, packing of the polymer may be increased by increasing the regularity of the polymer chains. Accordingly, the dichroic dye 72 may be prevented from moving toward the surface of the polarizing film 70 or migrating into another layer by increasing the arrangement of the dichroic dye 72 dispersed in the hydrophobic polymer 71 and by blocking or preventing migration of the dichroic dye 72 at room temperature and/or a high temperature. Accordingly, the polarizing film 70 may be prevented from degradation of properties by reducing the loss of the dichroic dye 72 from the polarizing film.

The migration and/or loss of the dichroic dye 72 may particularly occur during a high temperature process and/or in a process of being allowed to stand at room temperature or a high temperature. The polarizing film 70 may have a variation ratio (ΔT) light transmittance and a variation ratio of polarization efficiency (ΔPE) of about 1.0% or less after standing at 85° C. for 100 hours by using the polypropylene-based polymer to decrease the migration and/or loss of the dichroic dye 72. Accordingly, the polarizing film may be prevented from degradation of optical properties in a subsequent high temperature process and/or in a process of being allowed to stand at room temperature or a high temperature, and thus may have higher reliability.

The polypropylene-based polymer may have, for example, a distribution of a molecular weight within the range, when polymerized using a metallocene catalyst. The metallocene catalyst may be, for example a zirconocene complex or a hafnocene complex, but is not limited thereto.

For example, when a zirconocene complex is used to polymerize the polypropylene-based polymer, the polypropylene-based polymer may include a small amount of zirconium (Zr). The zirconium (Zr) may be included in an amount of about 0.01 ppm or greater, based on the total amount of the polypropylene-based polymer, for example, in an amount of about 0.05 ppm to about 50 ppm within the range, for example, in an amount of about 0.1 ppm to about 50 ppm within the range, for example, in an amount of about 0.2 ppm to about 50 ppm within the range, and for example, in an amount of 0.3 ppm to about 50 ppm within the range.

For example, when a hafnocene complex is used to polymerize a polypropylene-based polymer, the polypropylene-based polymer may include a small amount of hafnium (Hf). The hafnium (Hf) may be included in an amount of about 0.01 ppm or greater based on the total amount of the polypropylene-based polymer, in an amount of about 0.05 ppm to about 50 ppm within the range, in an amount of about 0.1 ppm to about 50 ppm within the range, in an amount of about 0.2 ppm to about 50 ppm within the range, or in an amount of 0.3 ppm to about 50 ppm within the range.

The polymerization of the polypropylene-based polymer may further utilize an auxiliary catalyst other than the metallocene catalyst during the polymerization process. For example, an aluminum-containing catalyst such as methyl aluminoxane may be used.

The polymerization of the polypropylene-based polymer may not use a ziegler-Natta catalyst during the polymerization process, and thus no magnesium (Mg) and titanium (Ti) may be used, or only a very small amount of the magnesium (Mg) and the titanium (Ti) may be used. For example, the polypropylene-based polymer may include about 1.0 ppm or less of magnesium (Mg) and about 0.5 ppm or less of titanium (Ti), for example about 0.7 ppm or less of magnesium (Mg) and about 0.3 ppm or less of titanium (Ti) within the range, and for example, about 0.5 ppm or less of magnesium (Mg) and about 0.1 ppm or less of titanium (Ti) within the range, and for example no magnesium (Mg) and no titanium (Ti).

The polypropylene-based polymer may have, for example, a melt flow index (MFI) of about 0.1 g/10 min to about 15 g/10 min. Herein, the melt flow index (MFI) refers to the amount in grams of a polymer in a molten state flowing per 10 minutes, and relates to the viscosity of the polymer in a molten state. The melt flow index is inversely proportional to the viscosity of the polypropylene-based polymer. In other words, the lower the melt flow index (MFI), the higher the polymer viscosity, while conversely, the higher the melt flow index (MFI), the lower the polymer viscosity. When the polypropylene-based polymer has a melt flow index (MFI) within the range, excessive crystals are not formed in the polymer and thus excellent light transmittance may be ensured and simultaneously workability may be effectively improved due to an appropriate viscosity for manufacturing a film. Specifically, the polypropylene may have a melt flow index (MFI) ranging from about 3 g/10 min to about 12 g/10 min.

The polypropylene-based polymer may have crystallinity of about 50% or less. When the polypropylene-based polymer has crystallinity within the range, haze may be lowered and thus excellent optical properties may be realized. For example, the polypropylene-based polymer may have crystallinity of about 30% to about 50%.

The hydrophobic polymer 71 may further include a polyethylene-polypropylene copolymer in addition to the polypropylene-based polymer. The polyethylene-polypropylene copolymer may include an ethylene content (mol %) and a propylene structural unit, and the ethylene content (mol %) may be included in an amount of about 0.5 mol % based on the total amount of the ethylene content (mol %) and the propylene structural unit. Within the range, the ethylene content (mol %) may be, for example, included in an amount of about 1 mol % or greater, for example in an amount of about 1 mol % to about 50 mol %, and for example in an amount of about 1 mol % to 25 mol %. When the polyethylene-polypropylene copolymer includes the ethylene content (mol %) within these ranges, the polyethylene-polypropylene copolymer may be effectively prevented or suppressed from phase-separation with the above polypropylene-based polymer and elongated in a higher elongation rate as well as have excellent light transmittance and arrangement, and thus realize improved polarization characteristics.

The polyethylene-polypropylene copolymer may have a distribution of a molecular weight of about 1 to about 5. The polyethylene-polypropylene copolymer may have for example a distribution of a molecular weight of about 1.5 to about 4.5 within the range, and for example, a distribution of a molecular weight of about 1.8 to about 4.3 within the range.

The hydrophobic polymer 71 may further include, for example polyamide, polyester, polyacryl, polystyrene, a copolymer thereof, or a combination thereof in addition to the polypropylene-based polymer. The hydrophobic polymer 71 may further include, for example polyethylene terephthalate (PET), polyethylene terephthalate glycol (PETG), polyethylene naphthalate (PEN), nylon, a copolymer thereof, or a combination thereof.

The polarizing film 70 may be a melt-blend of the hydrophobic polymer 71 and the dichroic dye 72. The melt-blend may be obtained by melt-blending a composition including the hydrophobic polymer 71 and the dichroic dye 72 at a temperature of greater than or equal to the melting point (Tm) of the hydrophobic polymer 71.

The composition may include the hydrophobic polymer 71 and the dichroic dye 72 in a form of a solid such as a powder, and for example, may not include a solvent.

The polarizing film 70 may be, for example, manufactured by preparing a polypropylene-based polymer, melt-blending a hydrophobic polymer including the polypropylene-based polymer and a dichroic dye at a temperature of greater than or equal to a melting point of the hydrophobic polymer, molding the melt-blend, and elongating a molded body.

The polypropylene-based polymer may be prepared by polymerizing a propylene monomer using, for example, a zirconocene complex or a hafnocene complex as a catalyst as described above. Herein, the zirconocene catalyst or the hafnocene catalyst may be included in an amount of about 0.0001 mmol to about 0.1 mmol based on about 1 mol of the reaction monomer for the polypropylene-based polymer. Within the range, the zirconocene catalyst or the hafnocene catalyst may be, for example, included in the reaction in an amount of about 0.0005 mmol to about 0.05 mmol, based on 1 mole of the propylene monomer.

The polypropylene-based polymer may include about 0.5 mol % or less of an ethylene content (mol %) and may have a distribution of a molecular weight of about 1 to about 5, as described above. The hydrophobic polymer may further include a polyethylene-polypropylene copolymer including an ethylene content (mol %) in an amount of greater than about 0.5 mol % and/or another kind of polymer, as described above.

The melt-blending may be performed at a temperature of about 300° C. or less, and specifically, may be from about 50 to about 300° C.

The molding may include molding the melt-blend in a form of, for example, a sheet, and may performed, for example, by putting the melt-blend in the mold and pressing it with a high pressure or by discharging the melt-blend in a chill roll through a T-die.

The elongating of the molded body may include elongating the molded body in a uniaxial direction, and may be performed, for example, at a temperature ranging from about 30° C. to about 200° C. at an elongation rate ranging from about 400% to about 1000%. The elongation rate refers to a ratio of the length of the sheer after the elongation of the sheet to the length of the sheet before the elongation of the sheet, and means the elongation extent of the sheet after uniaxial elongation. The elongation direction may be the length direction of the dichroic dye 72.

The polarizing film 70 may have a relatively thin thickness of about 100 μm or less, for example about 30 μm to about 95 μm. When the polarization film 70 has a thickness within this range, it may be significantly thinner than a polarizing plate requiring a protective layer such as triacetyl cellulose (TAC) layer and may thus contribute to realizing a thin display device.

Hereinafter, an optical film including the polarizing film 70 is described.

FIG. 2 is a schematic cross-sectional view showing an optical film according to an embodiment.

An optical film 55 according to an embodiment includes the polarizing film 70, a retardation film 95 disposed on the polarizing film 70, and an adhesion layer 90 interposed between the polarizing film 70 and the retardation film 95.

The polarizing film 70 is the same as described above.

The retardation film 95 may include, for example, a λ/4 retardation film, a λ/2 retardation film, or a combination thereof.

The adhesion layer 90 may include, for example, a pressure sensitive sticking agent or a pressure sensitive adhesive. The adhesive layer may be omitted.

The optical film 55 may be formed on one surface or both surfaces of a display device. In particular, the optical film 55 may be formed on the screen side of the display and thus may prevent reflection of light inflowing from outside of the display device (hereinafter referred to as “external light”). Accordingly, deterioration in visibility due to reflection of external light may be prevented.

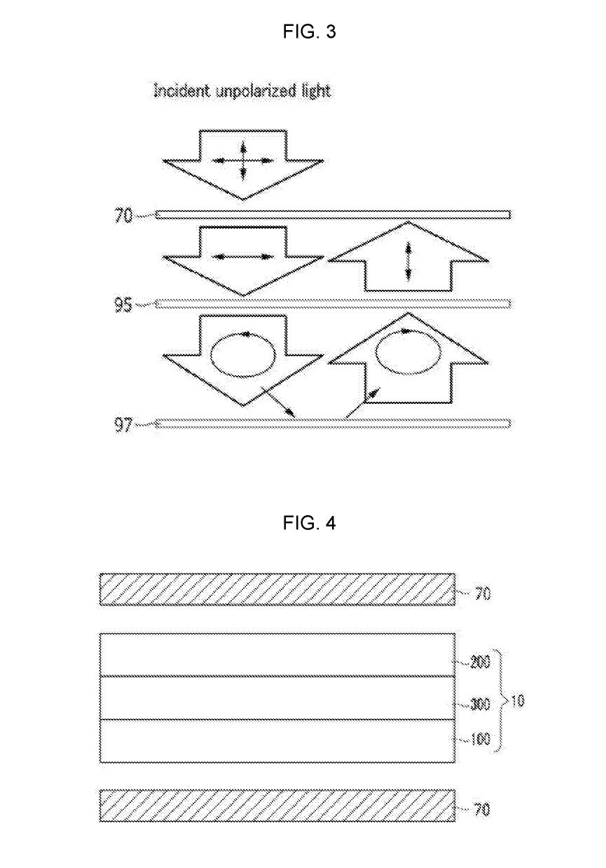

FIG. 3 is a schematic view showing a mechanism for preventing reflection of external light of an optical film according to an embodiment.

Referring to FIG. 3, when the incident unpolarized light having entered from the outside is passed through the polarization film 70, and the polarized light is shifted into circularly polarized light by passing through the retardation film 95, only a first polarized perpendicular component, which is one polarized perpendicular component of two polarized perpendicular components, is transmitted. When the circularly polarized light is reflected by a display panel 97 including a substrate, an electrode, and so on, there is a change to the circular polarization direction, and the circularly polarized light is passed through the retardation film 95 again, only the second polarized perpendicular component, which is the other polarized perpendicular component of the two polarized perpendicular components, may be transmitted. Since the second polarized perpendicular component is not passed through the polarization film 70, light does not exit to the outside, and thus an effect of preventing the external light reflection may be provided.

The polarization film or the optical film may be applied to various display devices.

The display device may be a liquid crystal display (LCD).

FIG. 4 is a cross-sectional view showing a liquid crystal display (LCD) according to an embodiment.

Referring to FIG. 4, a liquid crystal display (LCD) includes a liquid crystal display panel 10, and a polarization film 70 disposed on both the lower part and the upper part of the liquid crystal display panel 10.

The liquid crystal display panel 10 may be a twist nematic (TN) mode panel, a patterned vertical alignment (PVA) mode panel, an in-plane switching (IPS) mode panel, an optically compensated bend (OCB) mode panel, and the like.

The liquid crystal display panel 10 includes a first display plate 100, a second display plate 200, and a liquid crystal layer 300 interposed between the first display plate 100 and the second display plate 200.

The first display plate 100 may include, for example, a thin film transistor (not shown) formed on a substrate (not shown), and a first electric field generating electrode (not shown) connected thereto. The second display plate 200 may include, for example, a color filter (not shown) formed on the substrate and a second electric field generating electrode (not shown). However, the liquid crystal display panel is not limited thereto, and the color filter may be included in the first display plate 100, and both the first electric field generating electrode and the second electric field generating electrode may be disposed in the first display plate 100.

The liquid crystal layer 300 may include a plurality of liquid crystal molecules. The liquid crystal molecules may have positive or negative dielectric anisotropy. When the liquid crystal molecules have positive dielectric anisotropy, the long axis thereof may be aligned substantially parallel to the surface of the first display plate 100 and the second display plate 200 when not applying (e.g. in the absence of) an electric field, and may be aligned substantially perpendicular to the surface of the first display plate 100 and the second display plate 200 when applying (e.g. in the presence of) an electric field. On the contrary, when the liquid crystal molecules have negative dielectric anisotropy, the long axis thereof may be aligned substantially perpendicular to the surface of the first display plate 100 and the second display plate 200 when not applying an electric field, and may be aligned substantially parallel to the surface of the first display plate 100 and the second display plate 200 when applying an electric field.

The polarization film 70 is disposed on the outside of the liquid crystal display panel 10. Although it is shown to be disposed on both the upper part and lower part of the liquid crystal display panel 10 in FIG. 4, it may be formed on either the upper part or the lower part of the liquid crystal display panel 10.

The polarizing film 70 is the same as described above.

The display device may be an organic light emitting diode (OLED) display.

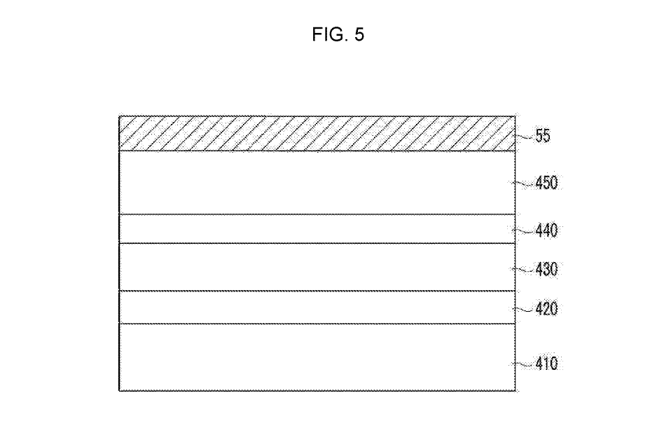

FIG. 5 is a cross-sectional view showing an organic light emitting diode (OLED) display according to an embodiment.

Referring to FIG. 5, an organic light emitting diode (OLED) display according to an embodiment includes a base substrate 410, a lower electrode 420, an organic emission layer 430, a upper electrode 440, an encapsulation substrate 450, and an optical film 55.

The base substrate 410 may be formed of glass or plastic.

Either of the lower electrode 420 and the upper electrode 440 may be an anode, while the other is a cathode. The anode is an electrode where holes are injected, and is formed of a transparent conductive material having a high work function and externally transmitting entered light, for example, a material such as indium tin oxide (ITO) or indium zinc oxide (IZO). The cathode is an electrode where electrons are injected, and is formed of a conductive material having a low work function and having no influence on an organic material, and includes, for example, aluminum (Al), calcium (Ca), barium (Ba), or a combination thereof.

The organic emission layer 430 includes an organic material capable of emitting light when a voltage is applied between the lower electrode 420 and the upper electrode 440.

An auxiliary layer (not shown) may be included between the lower electrode 420 and the organic emission layer 430 and between the upper electrode 440 and the organic emission layer 430. The auxiliary layer may include a hole transport layer for balancing electrons and holes, a hole injection layer (HIL), an electron injection layer (EIL), and an electron transport layer.

The encapsulation substrate 450 may be made of glass, a metal, or a polymer. The lower electrode 420, the organic emission layer 430, and the upper electrode 440 are sealed to prevent moisture and/or oxygen from flowing into the device.

The optical film 55 includes a retardation film 95 and a polarization film 70 as described above. The retardation film 95 may circularly polarize light passing through the polarization film 70 and generate a phase difference, and thus has an influence on reflection and absorption of the light.

The optical film 55 may be disposed on a light-emitting side. For example, the optical film 55 may be disposed outside of the base substrate 410 in a bottom emission type in which light emits from the base substrate 410, and outside of the encapsulation substrate 450 in a top emission type in which light emits from the encapsulation substrate 450.

Hereinafter, the present disclosure is illustrated in more detail with reference to examples. However, these examples are exemplary, and the present disclosure is not limited thereto.

### Preparation of Films

### Preparation Example 1

A composition for a polarization film is prepared by mixing a polypropylene-based polymer having the properties shown in Table 1 (Poly Mirae Co., Ltd.) and the dichroic dyes represented by Chemical Formulas A, B, C, and D in amounts of 0.2, 0.228, 0.286, and 0.286 parts by weight, respectively, based on 100 parts by weight of the polypropylene-based polymer.

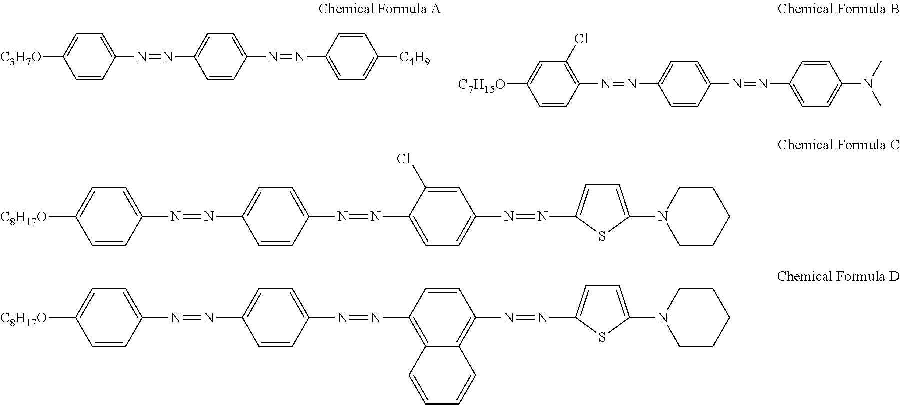

The composition for a polarization film is melt-blended at about 210° C. using an extruder (Process 11, Thermo Electron Corp.).

The melt-blend is further melted at about 230° C. using an extruder, (E20T, Collin Lab & Pilot Solutions), discharged through a T-die, and cooled down in a casting roll, manufacturing a sheet. The sheet is manufactured by setting the extruder at a screw speed of 40 rotations per minute (rpm) and the casting roll at 40° C. in an open casting method without using a touch roll.

### Comparative Preparation Example 1

A film is manufactured in the same method as described for Preparation Example 1 except using a different polypropylene-based polymer (Hanhwa Total Petrochemical Co., Ltd.) having the properties shown in Table 1.

### Comparative Preparation Example 2

A film is manufactured in the same method as Preparation Example 1 except using a different polypropylene-based polymer (Poly Mirae Co., Ltd.) having the properties shown in Table 1.

### Comparative Preparation Example 3

A film is manufactured in the same method as Preparation Example 1 except using a different polypropylene-based polymer (Japan Polychem Corp.) having the properties shown in Table 1.

### Comparative Preparation Example 4

A film is manufactured in the same method as Preparation Example 1 except using a different polypropylene-based polymer (Poly Mirae Co., Ltd.) having the properties shown in Table 1.

TABLE 1

| | | Amount of | Distribution | |
|---|---|---|---|---|
| | | ethylene | of a | |
| | Melt | content | molecular | |
| Polypropylene | Index | (mol %)* | weight | Catalyst |
| Preparation | 9 | ~0 | 3.8 | Main catalyst: |
| Example 1 | | | | zirconocene, |
| | | | | Auxiliary catalyst: |
| | | | | methyl |
| | | | | aluminoxane |
| Comparative | 7 | 1.4 | 6.3 | Ziegler-Natta |
| Preparation | | | | catalyst |
| Example 1 | | | | |
| Comparative | 8 | 3.8 | 5.1 | Ziegler-Natta |
| Preparation | | | | catalyst |
| Example 2 | | | | |
| Comparative | 7 | 3.4 | 4.0 | Main catalyst: |
| Preparation | | | | zirconocene, |
| Example 3 | | | | auxiliary catalyst: |
| | | | | methyl |
| | | | | aluminoxane |
| Comparative | 8 | ~0 | 6.1 | Ziegler-Natta |
| Preparation | | | | catalyst |
| Example 4 | | | | |

*the calculation of ethylene content is based on the method reported in the following paper - Macromolecules 1982, 15, 1150-1152)

### Evaluation 1

Metal components included in each film manufactured according to Preparation Example 1 and Comparative Preparation Examples 1 to 4 are analyzed.

The metal component analysis is performed in an inductively coupled plasma-atomic emission spectrometer (ICP-AES) after putting 2.0 g of a sample in a Pt furnace and incinerating the sample at 550° C. for 1 hour and adding 0.5 ml of HCl thereto to make a total volume of 20 ml.

The results are provided in Table 2.

TABLE 2

| | ICP-AES (ppm, mg/l) | | |
|---|---|---|---|
| Polypropylene | Mg | Ti | Zr |
| Preparation Example 1 | 0.2 | 0.0 | 0.4 |
| Comparative Preparation Example 1 | 50 | 0.8 | 0.0 |
| Comparative Preparation Example 2 | 7.3 | 0.7 | 0.0 |
| Comparative Preparation Example 3 | 0.5 | 0.0 | 0.2 |
| Comparative Preparation Example 4 | 59.2 | 0.6 | 0.0 |

### Evaluation 2

The films according to Preparation Example 1 and Comparative Preparation Examples 1 to 4 are visually evaluated by an observer to check whether a chill roll is contaminated or not during the manufacture of the films.

The surfaces of the chill roll during the manufacture of the films are visually examined by an observer to qualitatively compare the films.

The results are provided in Table 3.

TABLE 3

| | Contamination |
|---|---|
| Preparation Example 1 | X |
| Comparative Preparation Example 1 | ⊚ |
| Comparative Preparation Example 2 | ⊚ |
| Comparative Preparation Example 3 | ◯ |
| Comparative Preparation Example 4 | ◯ |

⊚: strong contamination,
◯: weak contamination,
X: no contamination

Referring to Table 3, the film according to Preparation Example 1 shows no contamination on the surface of a chill roll, and the films according to Comparative Preparation Examples 1 to 4 also show no contamination on the surface of a chill roll. However, as shown in Table 3, contamination is observed in Comparative Preparation Examples 1 to 4. The contamination is caused when a dichroic dye in a film moves toward the surface of the film. As shown herein, the film according to Preparation Example 1 shows relatively small migration and/or loss of the dichroic dye as compared with the films according to Comparative Preparation Examples 1 to 4.

### Evaluation 3

Whether a dichroic dye migrates within the films according to Preparation Example 1 and Comparative Preparation Examples 1 to 4 is evaluated.

The evaluation of whether or not a dichroic dye migrates within the film is performed by attaching a transparent tape (Scotch™ Tape, Cat. 122A, 3M) on each film prepared according to Preparation Example 1 and Comparative Preparation Examples 1 to 4, allowing the films to stand at 85° C. for 2 hours, and removing the transparent tape to measure the amount of the dichroic dye adhered on the transparent tape. The amount of the dichroic dye adhered on the transparent tape is measured by calculating a difference between initial absorbance and absorbance after the test.

The results are provided in Table 4.

TABLE 4

| | Absorbance change |
|---|---|
| | of Transparent tape |
| | (ΔAbs, @ 550 nm) |
| Preparation Example 1 | 0.052 |
| Comparative Preparation Example 1 | 0.229 |
| Comparative Preparation Example 2 | 0.203 |
| Comparative Preparation Example 3 | 0.124 |
| Comparative Preparation Example 4 | 0.074 |

Referring to Table 4, the film according to Preparation Example 1 shows a smaller amount of dichroic dye migrated toward the transparent tape as compared with the films according to Comparative Preparation Examples 1 to 4. Accordingly, the film according to Preparation Example 1 shows decreased migration and/or loss of the dichroic dye as compared with the films according to Comparative Preparation Examples 1 to 4.

### Manufacture of Polarization Film

### Example 1

The film according to Preparation Example 1 is elongated to 1000% at 115° C. in a uniaxial direction (a tensile tester, Instron Corp.), manufacturing a polarizing film.

### Comparative Example 1

A polarizing film is manufactured according to the same method as described in Example 1 except using the film according to Comparative Preparation Example 1 instead of the film according to Preparation Example 1.

### Comparative Example 2

A polarizing film is manufactured according to the same method as described in Example 1 except using the film according to Comparative Preparation Example 2 instead of the film according to Preparation Example 1.

### Comparative Example 3

A polarizing film is manufactured according to the same method as described in Example 1 except using the film according to Comparative Preparation Example 3 instead of the film according to Preparation Example 1.

### Comparative Example 4

A polarizing film is manufactured according to the same method as described in Example 1 except using the film according to Comparative Preparation Example 4 instead of the film according to Preparation Example 1.

### Evaluation 4

Each polarizing film according to Example 1 and Comparative Examples 1 to 4 is adhered on a glass substrate using a pressure sensitive adhesive (PS-47, Soken Electric Co., Ltd.), preparing a polarizing film for a test. Light transmittance, polarization efficiency, and color of the polarizing film for a test are initially measured or calculated and then measured or calculated again after allowing the films to stand at 85° C. for 100 hours.

The light transmittance is evaluated by using a V-7100 UV/Vis spectrophotometer (JASCO).

Polarization efficiency (PE) is determined using the measured light transmittance.

The polarization efficiency is obtained by Equation 1.

PE (%)=[(T∥−T⊥)/(T∥−T⊥)]1/2×100% Equation 1

In Equation 1,

PE denotes polarization efficiency,

T∥ denotes transmittance of a polarization film with regard to light entering parallel to the transmissive axis of the polarizing film,

T⊥ denotes transmittance of a polarizing film with regard to light entering perpendicular to the transmissive axis of the polarizing film.

The color change is evaluated using a spectrum colorimeter (CM-3600d, Konica Minolta Inc.) while light is supplied with a light source of D65 at reflection of 8° and optic acquisition of 2°.

The results are provided in Table 5.

TABLE 5

| | light | | | |
|---|---|---|---|---|
| | transmittance | polarization | | |
| | change | efficiency change | Color change | |
| | (ΔTs, %) | (ΔPE, %) | Δa* | Δb* |
| Example 1 | −0.79 | 0.09 | 0.09 | 2.79 |
| Comparative Example 1 | −5.48 | −1.86 | 1.66 | 10.18 |
| Comparative Example 2 | −7.36 | −0.87 | 1.36 | 9.27 |
| Comparative Example 3 | −5.70 | −0.44 | 0.80 | 7.91 |
| Comparative Example 4 | −3.67 | −0.03 | 0.08 | 3.81 |

Referring to Table 5, the polarizing film according to Example 1 exhibits a small change in light transmittance, small change in polarization efficiency, and minimal color changes as compared with the polarizing films according to Comparative Examples 1 to 4 after each film is allowed to stand for a defined period of time at a high temperature. Accordingly, the polarizing film according to Example 1 has a small migration and/or loss of a dichroic dye compared with the polarizing films according to Comparative Examples 1 to 4 and thus may be prevented from degradation of optical properties.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A polarizing film comprising
a hydrophobic polymer and a dichroic dye,
wherein the hydrophobic polymer comprises a polypropylene polymer comprising about 0.5 mol % or less of an ethylene content (mol %), and has a distribution of a molecular weight of about 1 to about 5.

2. The polarizing film of claim 1, wherein the polypropylene polymer comprises about 0.01 parts per million or greater of zirconium or hafnium.

3. The polarizing film of claim 2, wherein the polypropylene polymer comprises about 0.05 parts per million to about 50 parts per million of zirconium or hafnium.

4. The polarizing film of claim 1, wherein the polypropylene polymer comprises about 1.0 parts per million or less of magnesium and about 0.5 parts per million or less of titanium.

5. The polarizing film of claim 1, wherein the polypropylene polymer has a melt flow index of about 0.1 grams per 10 minutes to about 15 grams per 10 minutes.

6. The polarizing film of claim 1, wherein the hydrophobic polymer further comprises a polyethylene-polypropylene copolymer comprising an ethylene content (mol %) in an amount of greater than about 0.5 mol %.

7. The polarizing film of claim 6, wherein the polyethylene-polypropylene copolymer has a distribution of a molecular weight of about 1 to about 5.

8. The polarizing film of claim 1, wherein the dichroic dye comprises at least one dichroic dye having a maximum absorption wavelength at about 380 nanometers to about 780 nanometers.

9. The polarizing film of claim 1, wherein the dichroic dye is included in an amount of about 0.01 parts by weight to about 2 parts by weight based on 100 parts by weight of the hydrophobic polymer.

10. The polarizing film of claim 1, wherein the polarizing film is a melt-blend of the hydrophobic polymer and the dichroic dye.

11. The polarizing film of claim 1, wherein the polarizing film is elongated in a uniaxial direction.

12. The polarizing film of claim 1, wherein the polarizing film has a light transmittance variation ratio of about 1.0% or less and a variation ratio of polarization efficiency of about 1.0% or less, after standing at about 85° C. for about 100 hours.

13. A method of manufacturing a polarizing film, comprising
polymerizing a propylene monomer using a zirconocene catalyst or a hafnocene catalyst to prepare a polypropylene polymer comprising about 0.5 mol % or less of an ethylene content (mol %), and having a distribution of a molecular weight of about 1 to about 5,
melt-blending a hydrophobic polymer comprising the polypropylene polymer and a dichroic dye at a temperature of greater than or equal to a melting point of the hydrophobic polymer,
molding the melt-blend, and
elongating a molded body.

14. The method of claim 13, wherein in the preparing of the polypropylene-based polymer, the zirconocene catalyst or the hafnocene catalyst is included in an amount of about 0.0001 millimole to about 0.1 millimole, based on 1 mole of the propylene monomer.

15. The method of claim 13, wherein the hydrophobic polymer further comprises a polyethylene-polypropylene copolymer comprising an ethylene content (mol %) in an amount of greater than about 0.5 mol %.

16. The method of claim 15, wherein the polyethylene-polypropylene copolymer has a distribution of a molecular weight of about 1 to about 5.

17. An optical film comprising
the polarizing film of claim 1, and
a retardation film on the polarizing film.

18. The optical film of claim 17, wherein the retardation film comprises a λ/4 retardation film, a λ/2 retardation film, or a combination thereof.

19. A display device comprising the polarizing film of claim 1.

20. A display device comprising the optical film of claim 17.
